(19) United States
(12) Patent Application Publication
(10) Pub. No.: US 2005/0141838 A1
(43) Pub. Date: Jun. 30, 2005

(54) Optical waveguide device and manufacturing method thereof

(76) Inventor: Kouki Sato, Tokyo (JP)

Correspondence Address: LADAS & PARRY LLP, 224 SOUTH MICHIGAN AVENUE, SUITE 1200, CHICAGO, IL, 60604, US

(21) Appl. No.: 10/930,598

(22) Filed: Aug. 31, 2004

(30) Foreign Application Priority Data
Dec. 26, 2003 (JP) 2003-435196

(51) Int. Cl. H01L 21/00; G02B 6/30; G02B 6/10

(52) U.S. Cl. 385/129; 438/31

(57) ABSTRACT

An optical waveguide device and a manufacturing method thereof are disclosed. The optical waveguide device includes an end surface having a substrate, a clad layer on the substrate and a waveguide in the clad layer. The end surface is connected to an optical fiber array having at least one optical fiber via adhesive. An end surface of the waveguide is sloped by a slope angle θ in a direction orthogonal to an optical axis of the waveguide. A notch part is formed on an end surface of the substrate. According to the present invention, it is possible to improve productivity thereof by shortening processing time required to process the end surface of the waveguide and strengthen bonding intensity between the optical waveguide device and the optical fiber array.

### BACKGROUND OF THE INVENTION

1. Field of the Invention

The present invention relates to an optical waveguide device and a manufacturing method thereof. More particularly, the present invention relates to an optical waveguide device and a manufacturing method thereof in which an optical fiber array incorporating an optical fiber is connected to a waveguide via adhesive.

2. Description of the Related Art

Recent widespread use of optical fiber communication networks has stimulated development of high-performance optical parts. Typically, such optical parts are categorized into three groups: micro-optical parts, optical fiber parts and optical waveguide parts. Among these groups, especially, optical waveguide parts are spotlighted in that they can be suitably mass-produced and easily integrated on substrates. An optical waveguide module is a kind of these optical waveguide parts. An optical waveguide module typically multiplexes incoming light over an optical fiber into a plurality of outgoing rays of light. For example, such an optical waveguide module may be used as branching means for branching light toward individual houses.

FIG. 1 is a side view showing a conventional optical waveguide module. In FIG. 1, the X-axis direction represents an optical axis direction of a waveguide 148, and the Z-axis direction represents a direction orthogonal to the X-axis direction.

Referring to FIG. 1, an optical waveguide module 140 mainly includes an input-side optical fiber array 142, an optical waveguide device 146 and an output-side optical fiber array 151.

The input-side optical fiber array 142 includes a substrate 143 and a holding layer 144. The holding layer 144 is formed on the substrate 143. An input-side optical fiber 141 is provided between the holding layer 144 and the substrate 143.

The output-side optical fiber array 151 includes a substrate 152 and a holding layer 153. The holding layer 153 is formed on the substrate 152. A tape fiber 156 is provided between the substrate 152 and the holding layer 153. The tape fiber 156 is provided with four output optical fibers.

The optical waveguide device 146 includes a substrate 147, a waveguide 148 and a clad layer 149. The clad layer 149 is formed on the substrate 147, and the waveguide 148 is formed within the clad layer 149. In the illustration, the waveguide 148 multiplexes light from the optical fiber 141 into four rays of lights. An end surface 166 of the optical waveguide device 146 is bonded to an end surface 165 of the input-side optical fiber array 142 via adhesive 155, and thereby the optical fiber 141 can be optically connected to the waveguide 148.

In the optical waveguide module 140, end surfaces 148A and 148B of the waveguide 148 are sloped to have a predetermined slope angle with respect to the direction orthogonal to the optical axis of the waveguide 148, that is, the Z-axis direction, and are formed as mirror surfaces so as to attenuate reflected light returning to the input side. Thus, the end surfaces 166 and 167 of the optical waveguide device 146, the end surface 165 of the input-side optical fiber array 142, and the end surface 168 of the output-side optical fiber array 151 are arranged to have the predetermined slope angle, and are further fabricated as mirror surfaces. For example, such a predetermined slope angle may be 8 degrees.

Conventionally, for example, as disclosed in Japanese Laid-Open Patent Application No. 05-273432, the end surfaces 166 and 167 of the optical waveguide device 146 are formed in such a way that a layered member comprised of a substrate 147, a waveguide 148 and a clad layer 149 is cut with a dicing blade to have perpendicular end surfaces and then end surfaces 166 and 167 are processed with a polisher to have a predetermined slope angle. Through the polishing, the end surfaces 148A and 148B of the waveguide 148 are also processed to have the predetermined slope angle.

However, since such a polisher is designed for highly accurate surface processing, the processing speed is not so high in general. Thus, it takes much time to process the end surfaces 148A and 148B of the waveguide 148.

In addition, a very thin adhesive layer 155 and 157 is provided between the end surface 166 of the conventional optical waveguide device 146 and the end surface 165 of the input-side optical fiber array 142, and a very thin adhesive layer 157 is provided between the end surface 167 of the waveguide 146 and the end surface 168 of the output-side optical fiber array 151. Since each of these thin adhesive layers 155 and 157 is a few micrometer in thick, the optical waveguide device 140 is bonded to the input-side and output-side optical fiber arrays 142 and 151 at weak bonding intensity.

### SUMMARY OF THE INVENTION

It is a general object of the present invention to provide an optical waveguide device and a manufacturing method thereof in which one or more of the above-mentioned problems are eliminated.

A more specific object of the present invention is to provide an optical waveguide device and a manufacturing method that can improve productivity thereof by shortening processing time of end surfaces of a waveguide and strengthen bonding intensity with optical fiber arrays.

In order to achieve the above-mentioned objects, there is provided according to one aspect of the present invention an optical waveguide device, including: an end surface including a substrate, a clad layer on the substrate and a waveguide included in the clad layer, wherein the end surface is connected to an optical fiber array having at least one optical fiber via adhesive, the waveguide has an end surface sloped by a slope angle θ with respect to a direction orthogonal to an optical axis of the waveguide, and the substrate has a notch part on an end surface thereof.

According to one aspect of the invention, since the notch part is formed on an end surface of the substrate, the notch part can be filled with a larger amount of adhesive. As a result, it is possible to improve bonding intensity between the optical waveguide device and the optical fiber array.

Additionally, there is provided according to another aspect of the invention a method of manufacturing an optical waveguide device including an end surface having a substrate, a clad layer on the substrate and a waveguide included in the clad layer, wherein the end surface is connected to an optical fiber array having at least one optical fiber via adhesive, the waveguide has an end surface sloped by a slope angle θ with respect to a direction orthogonal to an optical axis of the waveguide, and the substrate has a notch part on an end surface thereof, the method including steps of: forming the notch part on the end surface of the substrate by grinding the end surface; and polishing the end surface of the waveguide to have the slope angle θ.

According to one aspect of the invention, the notch part is formed on the end surface of the substrate through grinding in shorter processing time than polishing. In this case, when the end surface of the waveguide is polished to have the slope angle θ, a smaller area only has to be polished than conventional methods. As a result, it is possible to shorten processing time required to process the end surface of the waveguide and improve productivity of the optical waveguide device.

In an embodiment of the invention, the notch part forming step may use a grinder to form the notch part, and the end surface polishing step may use a polisher to polish the end surface.

According to one aspect of the invention, the notch part forming step can be implemented by a grinder, and the polishing step can be implemented by a polisher.

In an embodiment of the invention, the method may further include a step of: providing a holding unit holding the optical waveguide device, wherein the grinder has a mounted part to mount the holding unit, the polisher has a mounted part to mount the holding unit, and the holding unit is configured to be attachable to the mounted part of the grinder and the mounted part of the polisher.

According to one aspect of the invention, the holding unit to hold the optical waveguide device can be attached alternately between the mounted part of the grinder and the mounted part of the polisher. Thus, when a polishing process starts after a grinding process, it becomes unnecessary to detach the optical waveguide device from the holding unit and then attach the optical waveguide device to a different holding unit of the polisher again. As a result, it is possible to improve productivity of the optical waveguide device.

In an embodiment of the invention, the grinder and the polisher may have respective processing members processing the optical waveguide device, and the holding unit may hold the optical waveguide device in such a way that the end surface of the waveguide is sloped by the slope angle θ with respect to the processing members.

According to one aspect of the invention, since the holding unit holds the optical waveguide device in such a way that the end surface of the waveguide can be sloped by the slope angle θ with respect to the processing members, it is unnecessary to conduct angle adjustment on the holding unit. As a result, it is possible to shorten processing time associated therewith and improve productivity of the optical waveguide device.

Other objects, features and advantages of the present invention will become more apparent from the following detailed description when read in conjunction with the accompanying drawings.

### BRIEF DESCRIPTION OF THE DRAWINGS

FIG. 1 shows an exemplary structure of a conventional optical waveguide module;

FIG. 2 schematically shows an exemplary structure of an optical waveguide module according to a first embodiment of the present invention;

FIG. 3 is an A directional view of the optical waveguide module shown in FIG. 2;

FIG. 4 schematically shows an exemplary structure of an optical waveguide device according to the first embodiment;

FIG. 5 is a cross-sectional view showing the optical waveguide device in FIG. 4 with respect to C-C line;

FIG. 6 schematically shows an exemplary structure of an optical waveguide device before processing of an end surface thereof according to the first embodiment;

FIG. 7 shows an exemplary structure of a holding unit according to the first embodiment;

FIG. 8 shows an exemplary structure of the holding unit under a status where an optical waveguide device is held;

FIG. 9 is a view showing the holding unit in FIG. 8 from D directional viewpoint;

FIG. 10 shows an exemplary positional relation before grinding between a grinder and a holding unit having an optical waveguide device according to the first embodiment;

FIG. 11 shows an exemplary positional relation during grinding between the grinder and the holding unit in FIG. 10;

FIG. 12 shows an exemplary structure of an optical waveguide device having a formed notch part according to the first embodiment;

FIG. 13 shows an exemplary structure of a polisher according to the first embodiment;

FIG. 14 is a plan view showing an exemplary base plate for mounting a holding unit according to the first embodiment;

FIG. 15 is a cross-sectional view showing the base plate in FIG. 14 with respect to G-G line;

FIG. 16 is an enlarged view of a processing area F shown in FIG. 13;

FIG. 17 shows an exemplary structure of an optical waveguide device after polishing according to the first embodiment;

FIG. 18 shows an exemplary structure of an optical waveguide device having a waveguide both end surfaces of which are polished according to the first embodiment;

FIG. 19 shows an exemplary structure of an optical waveguide module according to a second embodiment of the present invention;

FIG. 20 schematically shows an exemplary structure of an optical waveguide device according to the second embodiment; and

FIG. 21 schematically shows an exemplary structure of a holding unit according to the second embodiment.

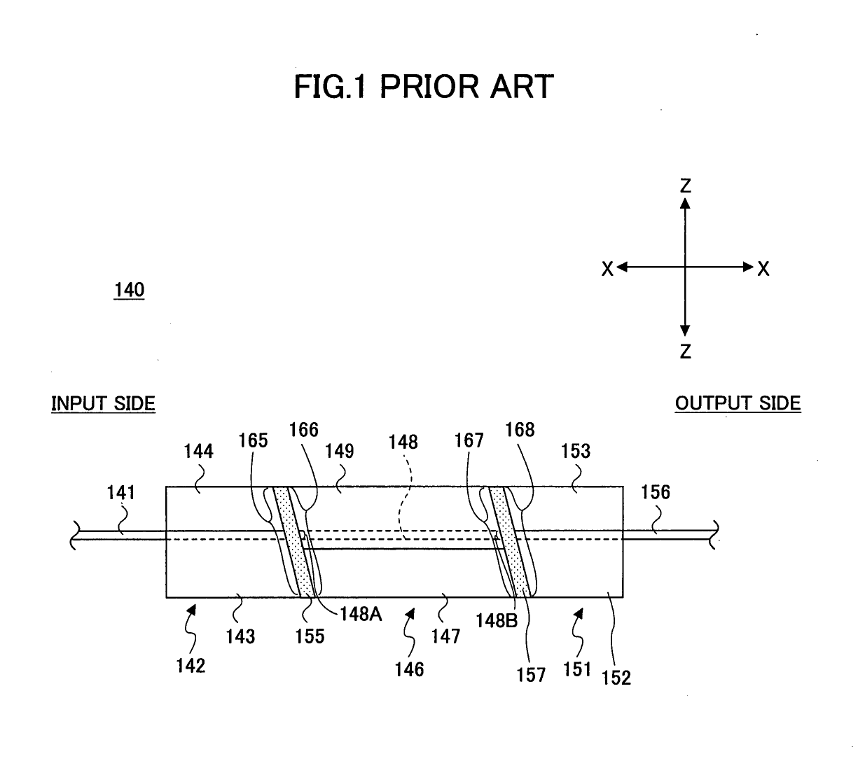

### DETAILED DESCRIPTION OF THE PREFERRED EMBODIMENTS

In the following, embodiments of the present invention will be described with reference to the accompanying drawings.

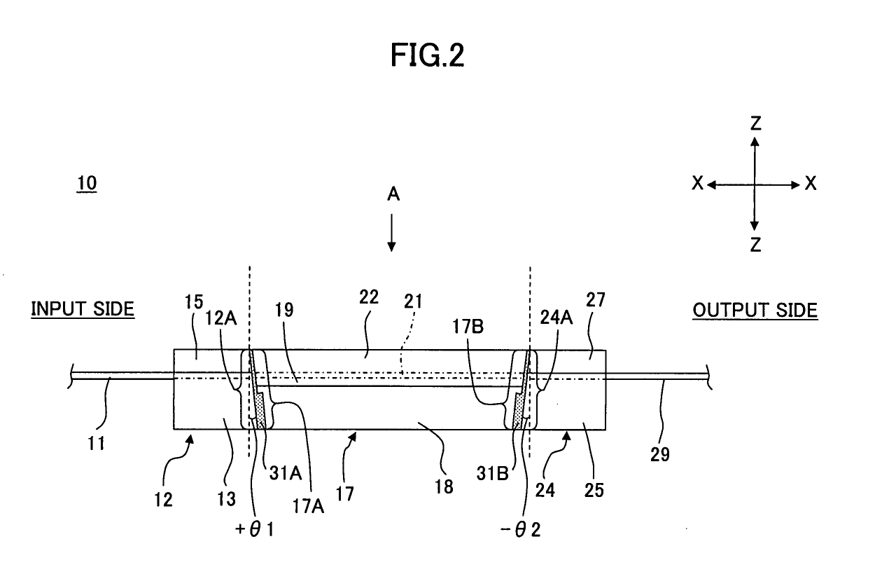

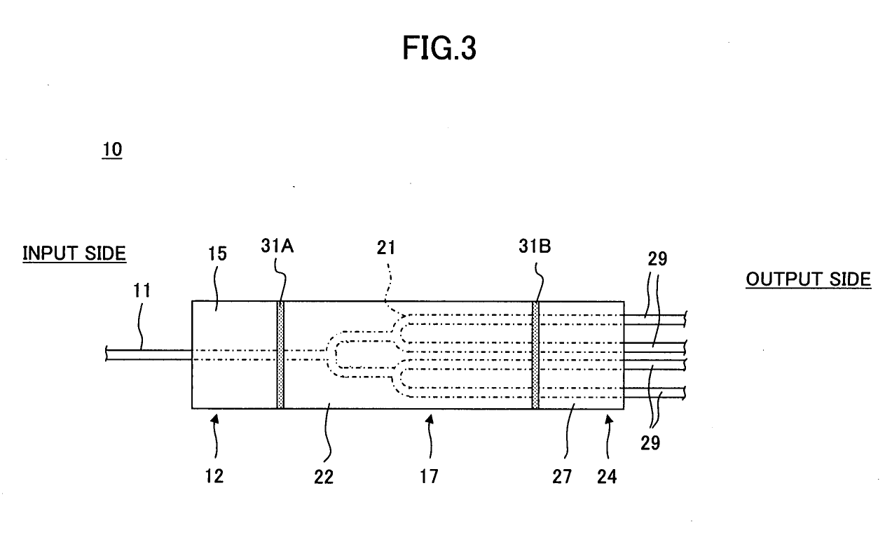

An optical waveguide module 10 according to a first embodiment of the present invention is described with reference to FIG. 2 and FIG. 3. FIG. 2 roughly illustrates an exemplary structure of the optical waveguide module 10. FIG. 3 is an A-directional view of the optical waveguide module 10 shown in FIG. 2. In FIG. 2, the X-axis direction represents the optical axis direction of a waveguide 21 of the optical waveguide module 10, and the Z-axis direction represents a direction orthogonal to the X-axis direction.

Referring to FIG. 2 and FIG. 3, the optical waveguide module 10 mainly includes an input-side optical fiber array 12, an output-side optical fiber array 24 and an optical waveguide device 17. In the following explanation, as illustrated in FIG. 2, if a surface is sloped in the illustration toward the right-hand side with respect to the Z-axis direction, a slope angle θ may be defined to be positive. On the other hand, if a surface is sloped in the illustration toward the left-hand side with respect to the Z-axis direction, the slope angle θ may be defined to be negative.

An end surface 12A of the input-side optical fiber array 12 is adhered on an end surface 17A of the optical waveguide device 17 with adhesive 31A, and thereby an optical fiber 11 is connected to a waveguide 21. On the other hand, an end surface 24A of the output-side optical fiber array 24 is adhered on an end surface 17B of the optical waveguide device 17 with adhesive 31B, and thereby four optical fibers 29 are connected to the waveguide 21.

The input-side optical fiber array 12 is used to lead incoming light from the optical fiber 11 to the waveguide 21. The input-side optical fiber array 12 includes a substrate 13 and a holding layer 15. The input-side optical fiber 11 is disposed at a predetermined position between the substrate 13 and the holding layer 15. Also, the end surface 12A at the connection side to the optical waveguide device 17 is processed to be a mirror surface. The end surface 12A is formed to have a slope angle +θ1, as illustrated in FIG. 2. For example, the slope angle +θ1 may be +8 degrees. It is noted that the slope angle +θ1 is set to have the same absolute value as a slope angle −θ1 of an end surface 34A described in detail below.

The output-side optical fiber array 24 includes a substrate 25 and a holding layer 27. The four optical fibers 29 are disposed at predetermined positions between the substrate 25 and the holding layer 27. Also, the end surface 24A at the connection side to the optical waveguide device 17 is processed to be a mirror surface. The end surface 24A is formed to have a slope angle −θ2, as illustrated in FIG. 2. For example, the slope angle −θ2 may be −8 degrees. It is noted that the slope angle −θ2 is set to have the same absolute value as a slope angle +θ2 of an end surface 34B of a waveguide 21 described in detail below. The output-side optical fiber array 24 is used to guide rays of light multiplexed by the waveguide 21 to the four optical fibers 29.

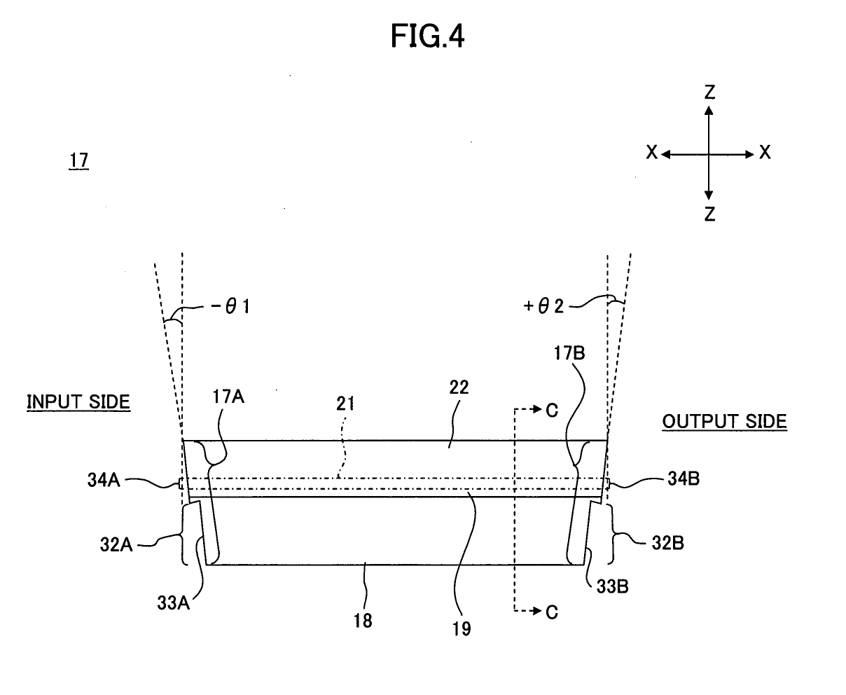

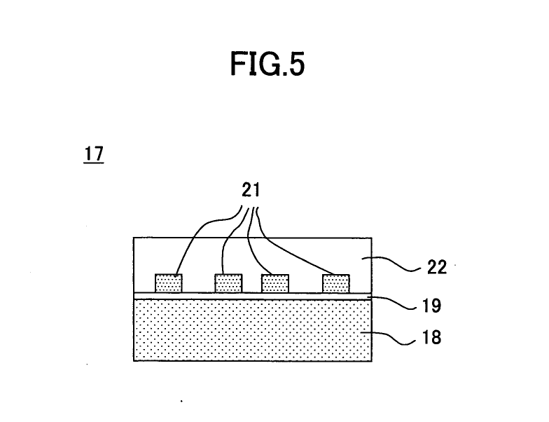

The optical waveguide device 17 is described with reference to FIG. 3 through FIG. 5. FIG. 4 roughly shows an exemplary structure of the optical waveguide device 17 according to the first embodiment. FIG. 5 is a cross-sectional view of the optical waveguide device 17 shown in FIG. 4 with respect to C-C.

Referring to FIG. 4 and FIG. 5, the optical waveguide device 17 mainly includes a substrate 18, a lower clad layer 19, a waveguide 21, an upper clad layer 22 and end surfaces 17A and 17B. The lower clad layer 19 is formed on the substrate 18, and the waveguide 21 is provided on the lower clad layer 19. As shown in FIG. 3, the waveguide 21 multiplexes or branches incoming light from the optical fiber 11 into four rays of light, and supplies the four rays of light to the four optical fibers 29. The upper clad layer 22 is formed to cover the waveguide 21.

The end surface 17A is located at the connection side to the input-side optical fiber array 12 via the adhesive 31A. As shown in FIG. 4, the end surface 17A includes an end surface 32A of the substrate 18 and an end surface 34A of the waveguide 21. A notch part 33A is formed on the end surface 32A of the substrate 18. Also, the end surface 34A of the waveguide 21 is processed to be a mirror surface, and is arranged to have a slope angle −θ1 (−8° in this embodiment) with respect to the Z-axis direction (the direction orthogonal to the optical axis of the waveguide 21).

The end surface 17B is located at the connection side to the output-side optical fiber array 24 via the adhesive 31B. As shown in FIG. 4, the end surface 17B includes an end surface 32B of the substrate 18 and an end surface 34B of the waveguide 21. A notch part 33B is formed on the end surface 32B of the substrate 18. Also, the end surface 34B of the waveguide 21 is processed to be a mirror surface, and is arranged to have a slope angle +θ2 (+8° in this embodiment) with respect to the Z-axis direction.

In this structure where the notch parts 33A and 33B are formed on the end surfaces 32A and 32B, respectively, of the optical waveguide device 17 as mentioned above, the notch parts 33A and 33B can be filled with a more amount of adhesive 31A and 31B than in conventional structures. As a result, it is possible to strengthen the bonding intensity between the input-side optical fiber array 12 and the optical waveguide device 17 and between the output-side optical fiber array 24 and the optical waveguide device 17.

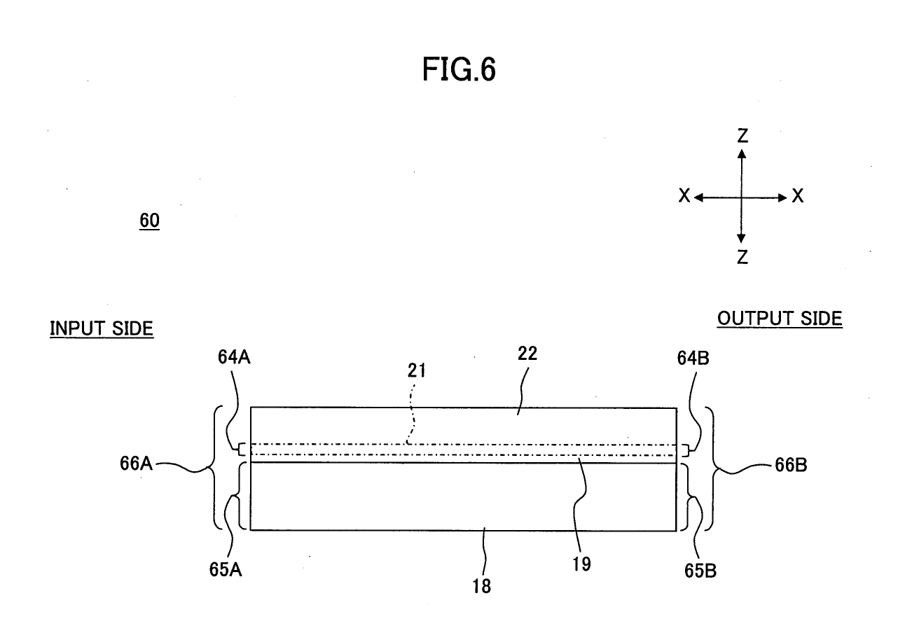

An exemplary structure of an optical waveguide device 60 before processing of end surfaces thereof is described with reference to FIG. 6. FIG. 6 roughly shows an exemplary structure of the optical waveguide device 60 before processing of end surfaces thereof. In FIG. 6, the same parts as those in FIG. 4 are designated by the same reference numerals.

Referring to FIG. 6, the optical waveguide device 60 before processing of end surfaces thereof mainly includes a substrate 18, a waveguide 21, a lower clad layer 19, an upper clad layer 22 and end surfaces 66A and 66B oriented orthogonally to the X-axis direction. The end surface 66A includes an end surface 64A of the waveguide 21 and an end surface 65A of the substrate 18. On the other hand, the end surface 66B includes an end surface 64B of the waveguide 21 and an end surface 65B of the substrate 18. Thus, the end surfaces 64A and 64B of the waveguide 21 before processing thereon are arranged to be oriented orthogonally to the X-axis direction.

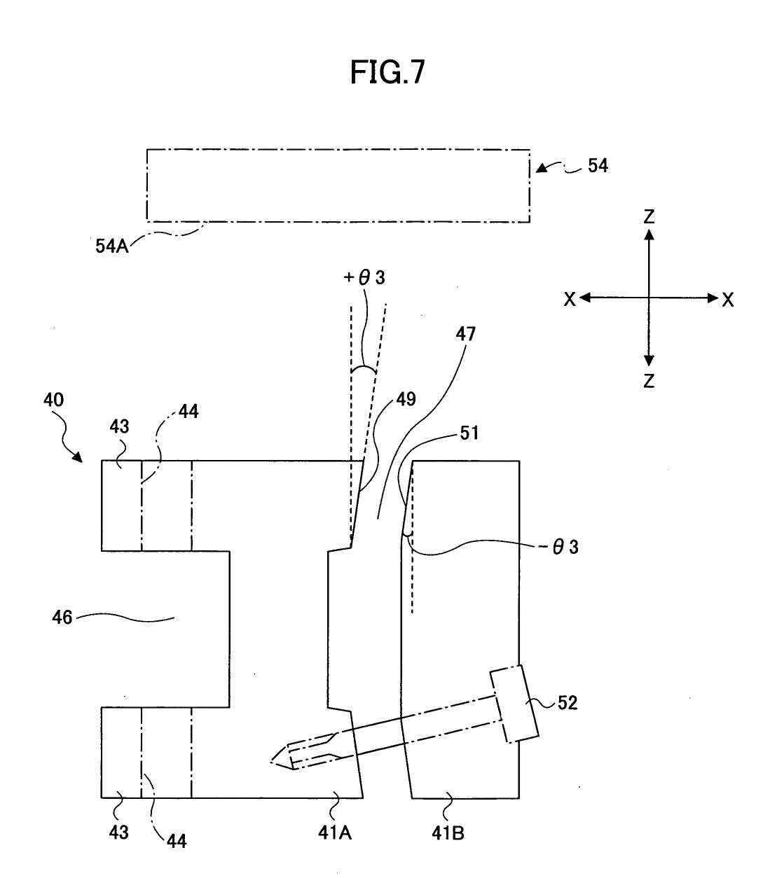

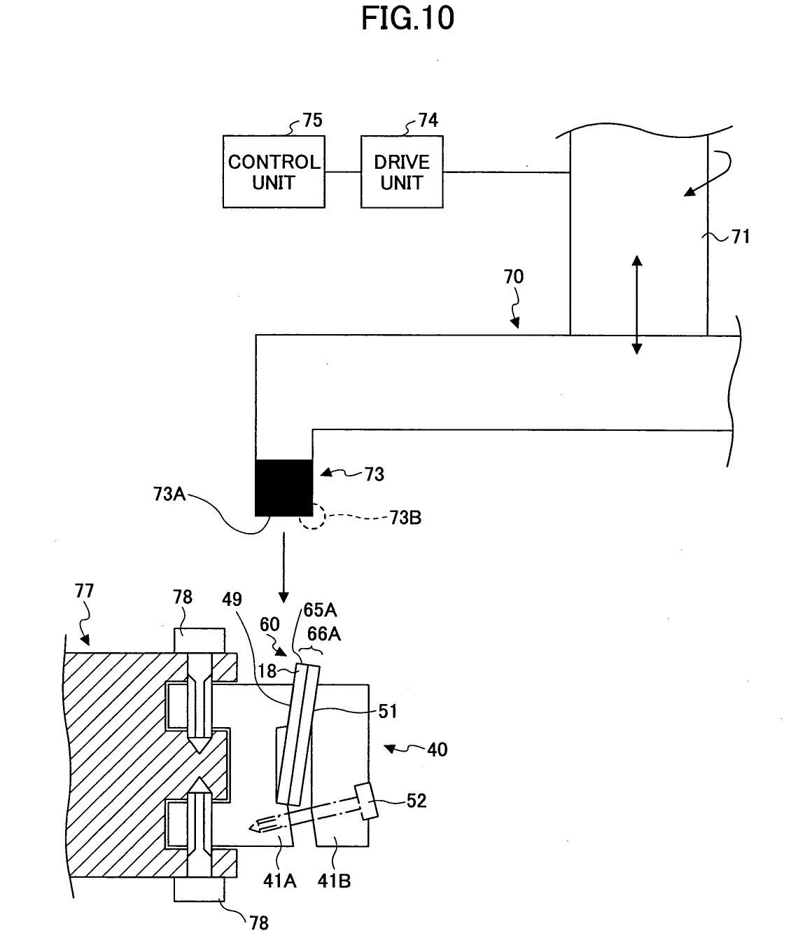

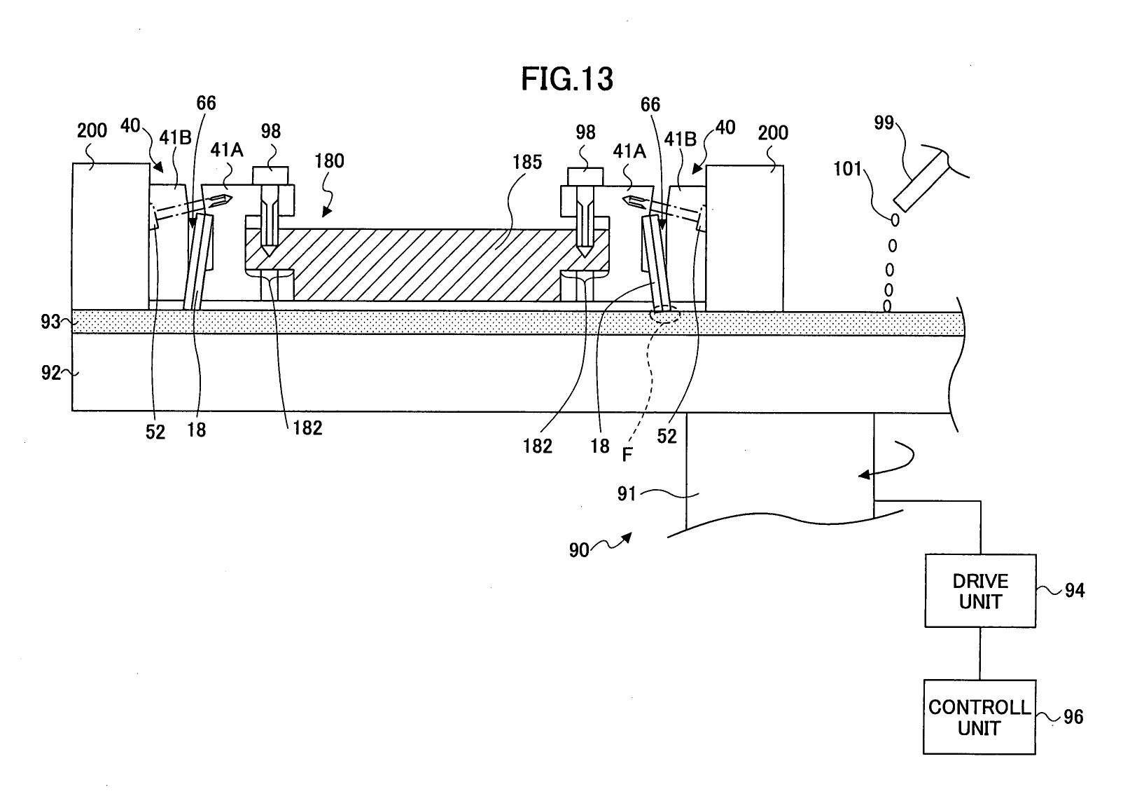

A holding unit 40 mounted to a grinder 70 (see FIG. 10) and a polisher 90 (see FIG. 13) is described with reference to FIG. 7 through FIG. 9. FIG. 7 shows an exemplary structure of the holding unit 40 according to the first embodiment. In FIG. 7, the Z-axis direction represents a direction orthogonal to a processing surface 54A of a processing member 54, and the X-axis direction represents a direction orthogonal to the Z-axis direction.

The holding unit 40 is used to keep the optical waveguide device 60. The holding unit 40 mainly includes a fixing-side member 41A for fixing a device, a holding-side member 41B for holding a device and a screw 52. The fixing-side member 41A is positioned at the side where the optical waveguide device 60 is fixed to a mounted part 77 (see FIG. 10) of the grinder 70 or a mounted part 182 (see FIG. 13) of the polisher 90. The fixing-side member 41A is provided with two convex parts 43, and a concave part 46 is formed between the two convex parts 43. Respective holes 44, through which screws can pierce, are formed in the convex parts 43. The holding unit 40 is installed by inserting screws through the holes 44 and screwing the mounted part 77 of the grinder 70 or the mounted part 182 of the polisher 90.

The fixing-side member 41A has a slope surface 49 in contact with an optical waveguide device 60. The slope surface 49 is formed to have a slope angle +θ3 (+8° in this embodiment) with respect to the Z-axis direction.

The holding-side member 41B is provided with a slope surface 51 in contact with an optical waveguide device 60. The slope surface 51 is formed to have a slope angle −θ3 (−8° in this embodiment) with respect to the Z-axis direction. The slope surface 51 is disposed to face the slope surface 49 in parallel. An area 47 to insert a plurality of optical waveguide devices 60 is formed between the slope surfaces 49 and 51.

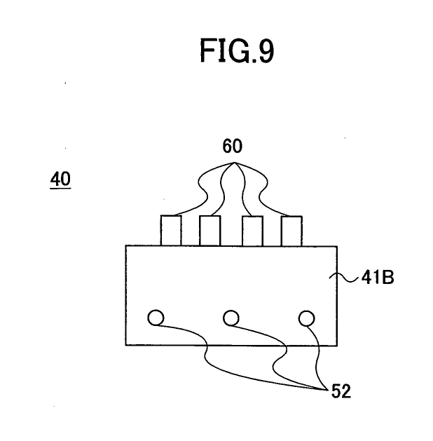

The holding-side member 41B is shifted to sandwich the plurality of optical waveguide devices 60 inserted in the area 47 between the slope surfaces 49 and 51. The screw 52 is used to fixably shift the holding-side member 41B to the fixing-side member 41A. Three screws 52 are used in this embodiment (see FIG. 9). If these three screws 52 are fastened, the holding unit 40 can retain the optical waveguide device 60. In contrast, if the three screws 52 are loosened, the optical waveguide device 60 can be detached.

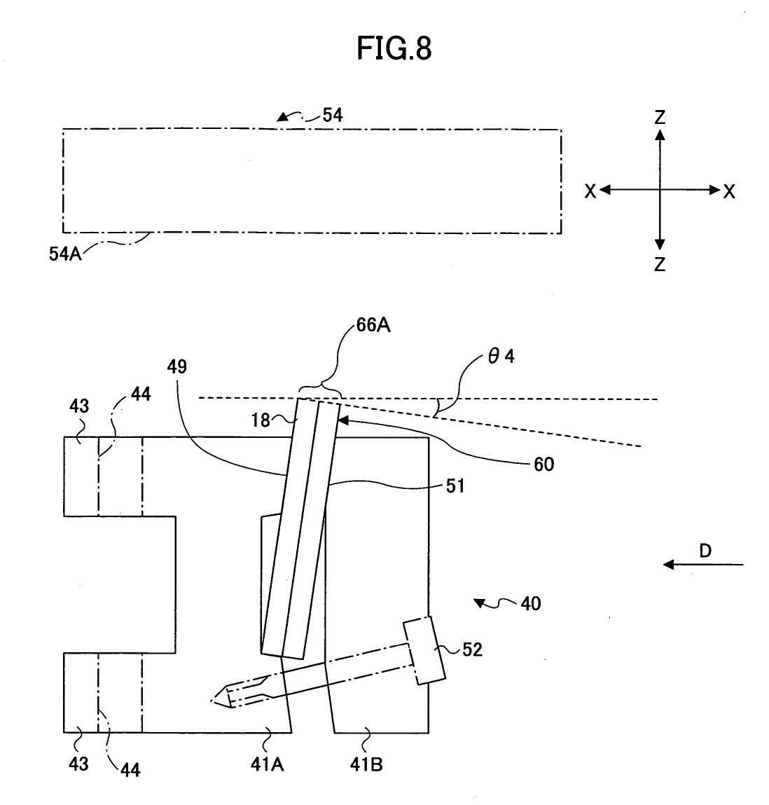

FIG. 8 shows an exemplary structure of the holding unit 40 under a status where the optical waveguide devices 60 are retained. FIG. 9 is a view from the D direction of the holding unit 40 shown in FIG. 8. As shown in FIG. 8 and FIG. 9, a plurality of (four) optical waveguide devices 60 are retained in the holding unit 40. Also, as shown in FIG. 8, the holding unit 40 retains the optical waveguide devices 60 in such a way that end surfaces 66A of the optical waveguide devices 60 can be sloped to have a slope angle θ4 (8°) with respect to the processing surface 54A of the processing member 54.

If the above-mentioned holding unit 40 is used, the end surfaces 66A and 66B can be processed under the status where the optical waveguide device 60 is fixed to the holding unit 40 in common use for the grinder 70 and the polisher 90. Thus, when polishing is started after grinding, it becomes unnecessary to detach the optical waveguide devices 60 from the holding unit 40 and then reattach the optical waveguide devices 60 to another holding unit dedicated to the polisher 90. As a result, it is possible to shorten processing time to attach and detach the optical waveguide devices 60 and improve productivity of the optical waveguide devices 60.

In addition, since the end surfaces 64A and 64B of the waveguide 21 are retained in the holding unit 40 to have the slope angle θ4, it becomes unnecessary to conduct angle adjustment on the holding unit 40 relative to processing members of the grinder 70 and the polisher 90. As a result, it is possible to accurately process the end surfaces 64A and 64B of the waveguide 21 in shorter processing time.

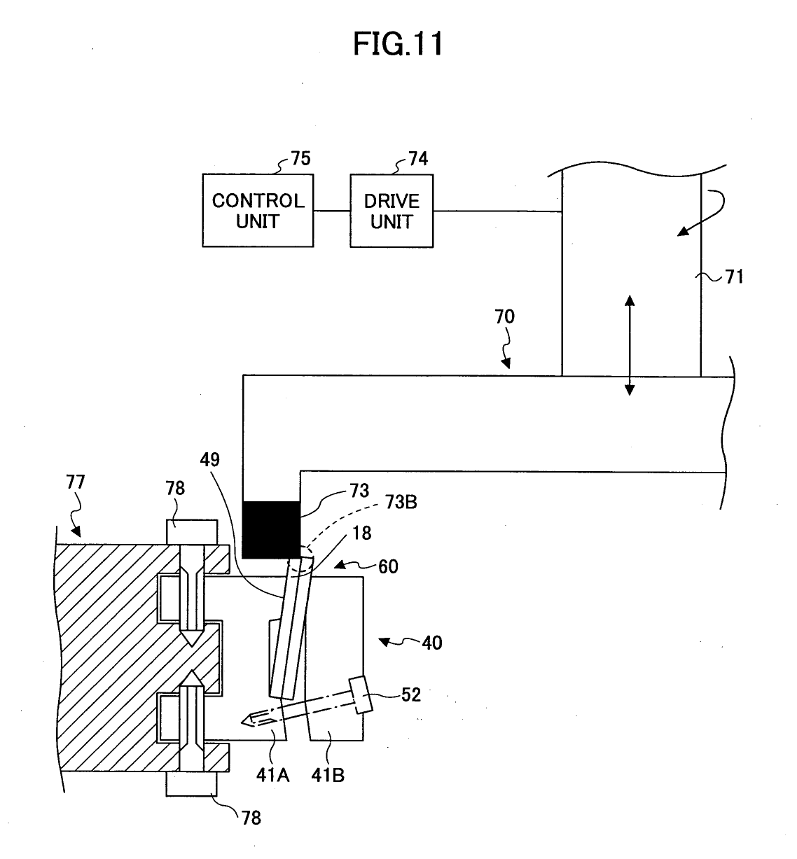

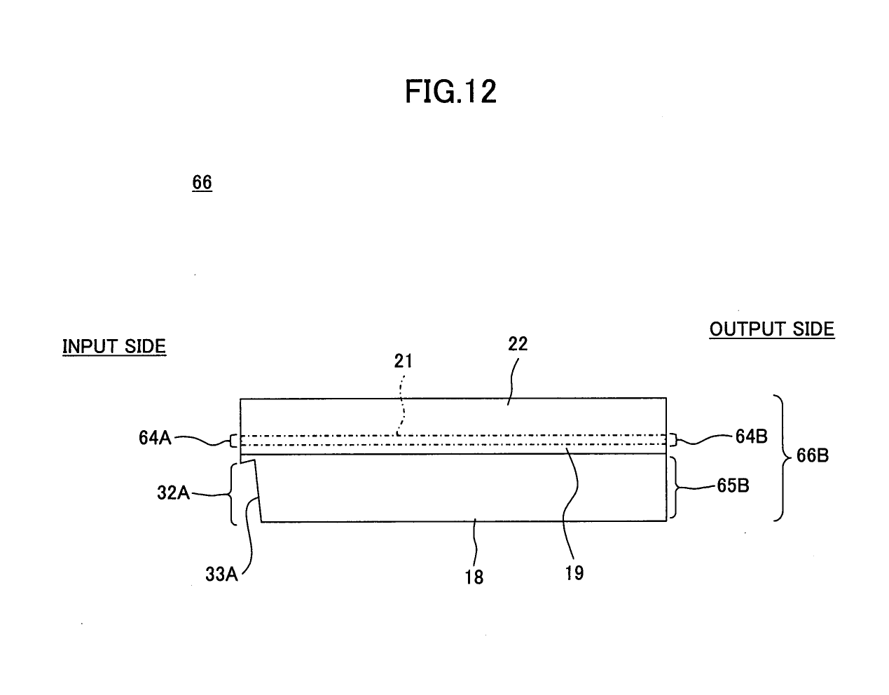

An exemplary method of forming a notch part is described with reference to FIG. 10 through FIG. 12 by using an example where the grinder 70 is used to form the notch part 32A on the end surface 65A. FIG. 10 shows an exemplary status of the grinder 70 before grinding. FIG. 11 shows an exemplary status of the grinder 70 during grinding. FIG. 12 shows an exemplary structure of an optical waveguide device 60 having a formed notch part 32A.

An exemplary structure of the grinder 70 is described with reference to FIG. 10 and FIG. 11. The grinder 70 mainly includes a main shaft 71, a cup-type grind stone 73 as a processing member, a drive device 74, a control device 75 and a mounted part 77 to install the holding unit 40.

The main shaft 71 is integrally provided with the cup-type grind stone 73 having a corner part 73B. A processing surface 73A of the cup-type grind stone 73 faces one or more optical waveguide devices 60. The control device 75 controls overall operation of the grinder 70 as well as the drive device 74.

The drive device 74 rotationally shifts the cup-type grind stone by rotationally driving the main shaft 71 so as to grind the end surface 65A of the substrate 18. The holding unit 40 holding the optical waveguide device 60 is installed to the mounted part 77 by using the screw 78. The optical waveguide device 60 is kept in the holding unit 40 in such a way that the substrate 18 can be in contact with the slope surface 49 of the fixing-side member 41A.

When the notch part 33A is formed by grinding, as illustrated in FIG. 11, the corner part 73B of the grind stone 73 is applied to be in contact with the end surface 65A of the substrate 18. As a result, it is possible to form the optical waveguide device 66 having the notch part 33A, as illustrated in FIG. 12, on the end surface 32A of the substrate 18. After formation of the notch part 33A, the holding unit 40 is detached from the mounted part 77 of the grinder 70 and then installed to the mounted part 182 of the polisher 90 (see FIG. 13).

An exemplary structure of the polisher 90 to process the end surfaces 64A and 64B of the waveguide 21 is described with reference to FIG. 13. FIG. 13 shows an exemplary structure of the polisher 90 during processing. In FIG. 13, a processing area F is a contact area between polishing fabric 93 and an optical waveguide device 66.

The polisher 90 includes a main shaft 91, a platen 92, a drive device 94, a control device 96, a polishing liquid supply part 99 and a base plate 180 for installing the holding unit 40. The platen 92 has almost round shape and is provided integrally with the main shaft 91. The polishing fabric 93, which works as a processing member, is disposed on the upper surface of the platen 92.

The polishing liquid supply part 99 is provided above the polishing fabric 93. The polishing liquid supply part 99 supplies polishing liquid 101 to the polishing fabric 93. The control device 96 controls overall operation of the polishing device 90 as well as the drive device 94. The drive device 94 rotationally drives the main shaft 91. When the main shaft 91 rotates, the platen 92 also rotates integrally with the main shaft 91, and thereby it is possible to process the end surface 64A of the waveguide 21 under a status that the end surface 64A remains in contact with the polishing fabric 93.

Since the polisher 90 is configured as a high-precision processing device capable of performing mirror surface treatment, the processing of the polisher 90 is considerably slow relative to that of the grinder 70. The polishing fabric 93 may be, for example, silk, foamed polyurethane, urethane nonwoven, and urethane suede fabric. The polishing liquid 101 may be liquid in which silica, alumina, ceria and others, particle diameter of which is less than 1 μm, are dispersed. In another embodiment, instead of the polishing fabric 93, a fixed platen, in which diamond particles having particle diameter of 0.5 to 3 μm are scattered, may be used.

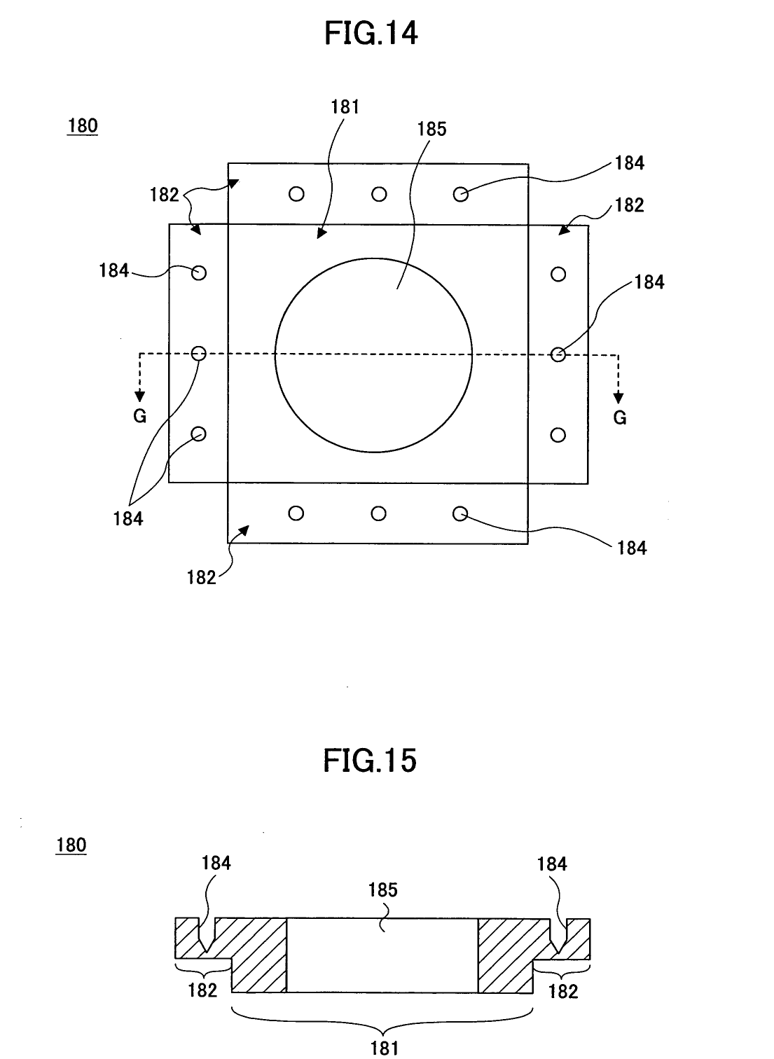

The base plate 180 for installing the holding unit 40 is described with reference to FIG. 13 through FIG. 15. FIG. 14 is a plan view of an exemplary structure of the base plate 180. FIG. 15 is a cross-sectional view of the base plate 180 shown in FIG. 14 with respect to G-G.

Referring to FIG. 14 and FIG. 15, the base plate 180 mainly includes a base body 181 and a mounted part 182.

The base body 181 has almost square shape. The mounted part 182 is integrally formed at four side-surface parts of the base body 181. The mounted part 182 is for mounting the holding unit 40.

Three screw locking parts 184 to lock screws 98 are formed in the mounted part 182. These screw locking parts 184 may be formed as female screws. The holding unit 40 can be attached to the base plate 180 by locking the screws 98 piercing through the holes 44 to the screw locking parts 184. A round modifying ring 200 is provided at the external circumferential part of the holding unit 40.

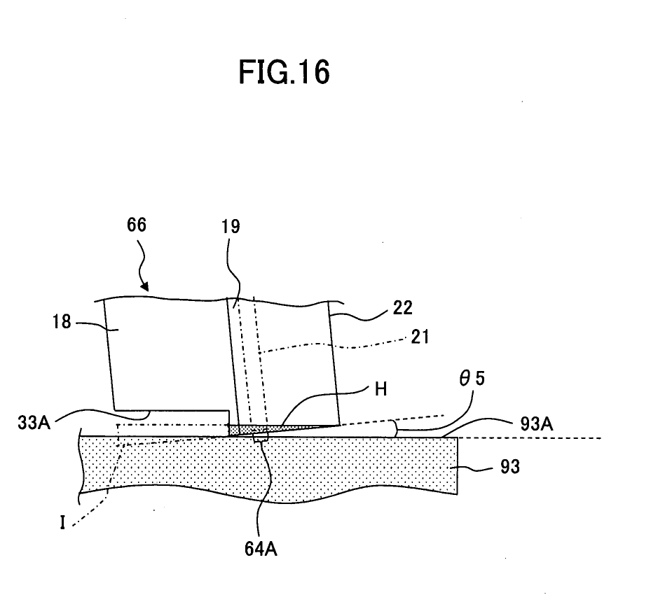

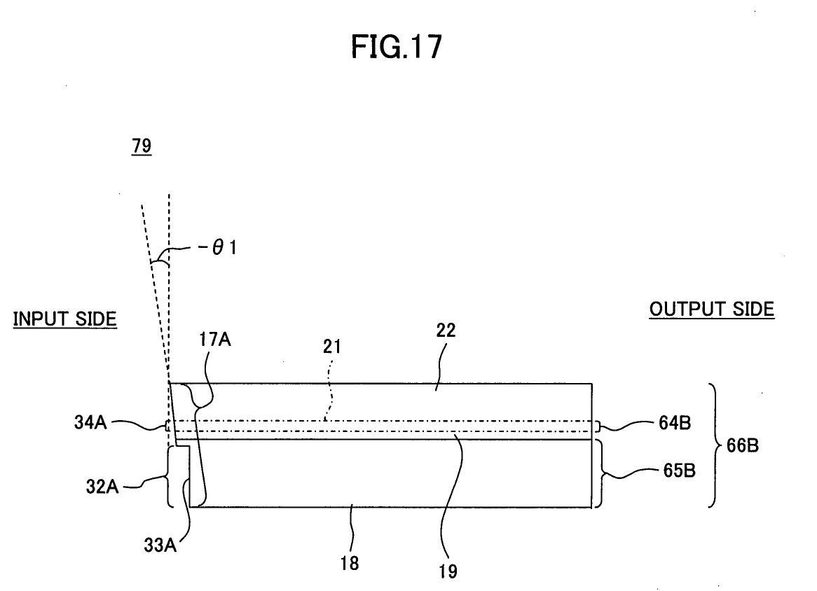

A polishing method according to this embodiment is described with reference to FIG. 16 through FIG. 18 by using a case where the end surface 64A of the waveguide 21 is polished. FIG. 16 is an enlarged view showing the processing area F enclosed by the dot line in FIG. 13. FIG. 17 shows an exemplary structure of an optical waveguide device after polishing. In FIG. 16, an area H must be polished in accordance with either of conventional methods or this method. An area I must be polished in accordance with any of conventional methods.

As illustrated in FIG. 16, the optical waveguide device 66 is held in the holding unit 40 in such a way that the end surface 64A of the waveguide 21 can be arranged to have a slope angle θ5 (8° in this embodiment) with respect to the processing surface 93A of the polishing fabric 93. Since the notch part 33A is formed in the optical waveguide device 66, the substrate 18 is not in contact with the polishing fabric 93 located around the notch part 33A (area corresponding to the area I) during polishing. Thus, it is unnecessary to polish the notch part 33A of the substrate 18. For this reason, only an area corresponding to the area H has to be polished. As a result, it is possible to form an optical waveguide device 79 having an end surface 34A sloped to have a slope angle −θ1, as illustrated in FIG. 17, by polishing a smaller area with less processing time.

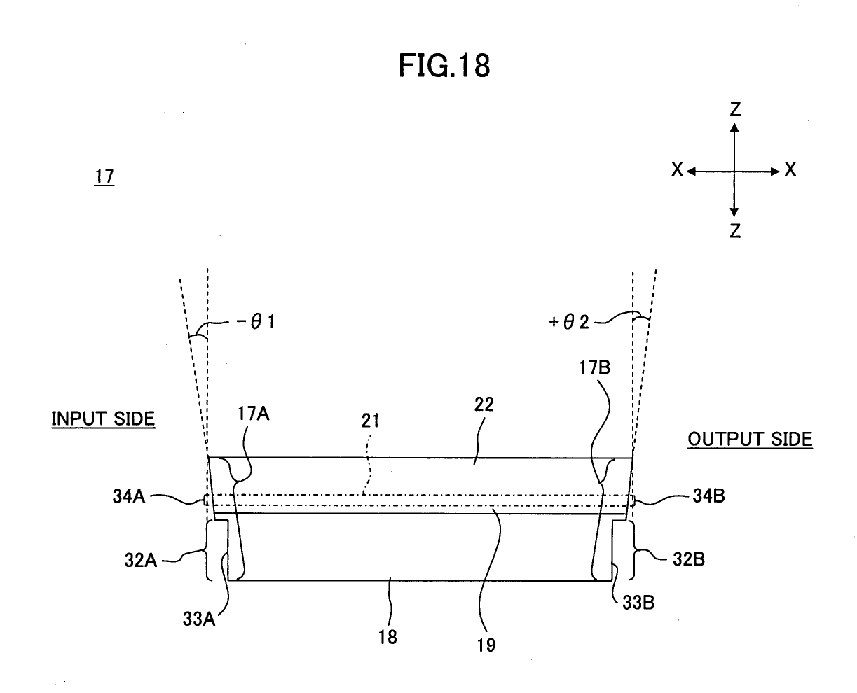

FIG. 18 shows an exemplary structure of an optical waveguide device 17 in which both end surfaces of a waveguide are polished. Also, in case of processing the other end surfaces 64B of the waveguide 21 so as to have the slope angle +θ2, as illustrated in FIG. 18, after the notch part 33B is formed on the end surface 65B of the substrate 18 in accordance with the same method as the above-mentioned grinding method, it is possible to manufacture the optical waveguide device 17 having the end surfaces 34B sloped to have the slope angle +θ2 in accordance with the same method as the above-mentioned polishing method.

According to the first embodiment, after the holding unit 40, to which the above-mentioned grinder 70 and polisher 90 can be installed, is used to form the notch parts 33A and 33B on end surfaces of the substrate 18 by grinding, the polisher 90 is used to polish the end surfaces 64A and 64B of the waveguide 21. Thus, it is possible to shorten time to attach and detach an optical waveguide device to/from the holding unit 40 and processing time for the end surfaces 64A and 64B of the waveguide 21. As a result, it is possible to improve productivity of the optical waveguide device 17. Specifically, this embodiment can process the end surfaces 64A and 64B of the waveguide 21 for about half processing time of that required by conventional methods.

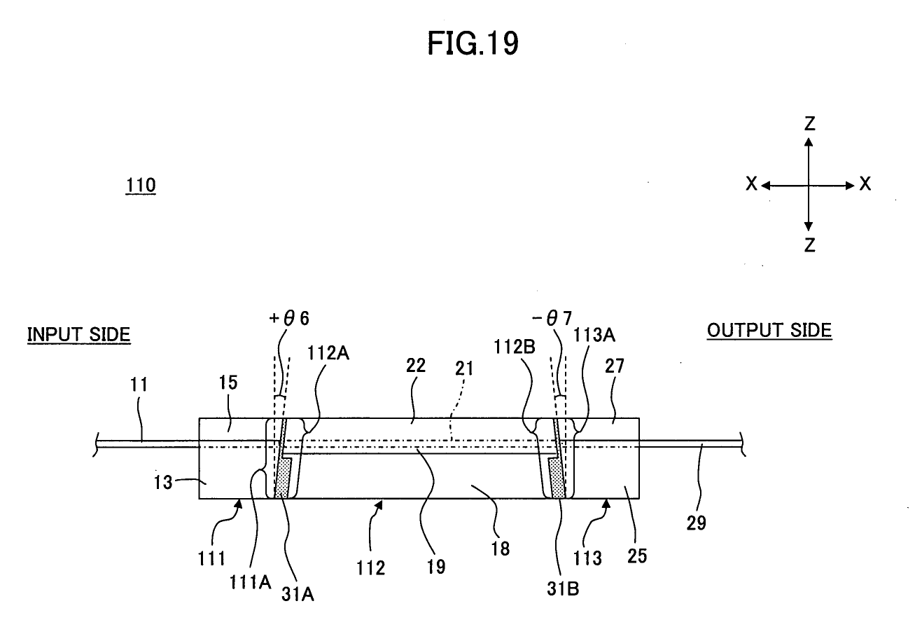

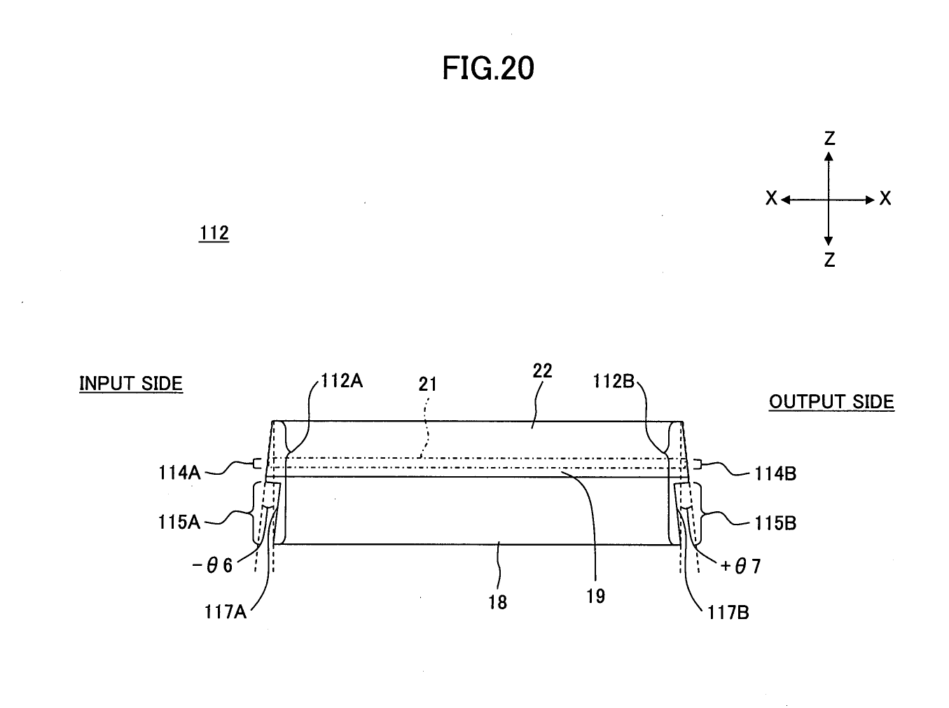

An optical waveguide module 110 according to a second embodiment of the present invention is described with reference to FIG. 19 and FIG. 20. FIG. 19 roughly shows an exemplary structure of the optical waveguide module 110. FIG. 20 roughly shows an exemplary structure of an optical waveguide device according to the second embodiment. In FIG. 19 and FIG. 20, the same components as those of the optical waveguide module 10 shown in FIG. 2 are designated by the same reference numerals, and the description thereof is omitted. Also, in the following, if a surface is sloped in the illustration toward the right-hand side with respect to the Z-axis by a slope angle θ, it is said that the surface is sloped to have the slope angle +θ. On the other hand, it a surface is sloped in the illustration toward the left-hand side with respect to the Z-axis by a slope angle θ, it is said that the surface is sloped to have the slope angle −θ.

Referring to FIG. 19 and FIG. 20, the optical waveguide module 110 mainly includes an input-side optical fiber array 111, an output-side optical fiber array 113 and an optical waveguide device 112. An end surface 111A of the input-side optical fiber array 111 is adhered to an end surface 112A of the optical waveguide device 112 via adhesive 31A, and thereby an input-side optical fiber 11 can be connected to a waveguide 21. On the other hand, an end surface 113A of the output-side optical fiber array 113 is adhered to an end surface 112B of the optical waveguide device 112 via adhesive 31B, and thereby four output-side optical fibers 29 can be connected to the waveguide 21.

The input-side optical fiber array 111 includes a substrate 13, a holding layer 15 and an end surface 11A. The input-side optical fiber 11 is provided at a predetermined position between the substrate 13 and the holding layer 15. The end surface 111A is connected to the optical waveguide device 112. The end surface 111A is processed to be a mirror surface, and is arranged to have a slope angle +θ6 with respect to the Z-axis direction. For example, the slope angle +θ6 may be +8 degrees.

The output-side optical fiber array 113 includes a substrate 25, a holding layer 27 and an end surface 113A. The four optical fibers 29 are provided at predetermined positions between the substrate 25 and the holding layer 27. The end surface 113A is connected to the optical waveguide device 112. The end surface 113A is processed to be a mirror surface, and is arranged to have a slope angle −θ7 with respect to the Z-axis direction. For example, the slope angle −θ7 may be −8 degrees.

The optical waveguide device 112 according to the second embodiment is described. The optical waveguide device 112 mainly includes a substrate 18, a lower clad layer 19, a waveguide 21, an upper clad layer 22 and end surfaces 112A and 112B.

The end surface 112A is connected to the input-side optical fiber array 111. As shown in FIG. 20, the end surface 112A includes an end surface 115A of the substrate 18 and an end surface 114A of the waveguide 21. A notch part 117A is formed on the end surface 115A of the substrate 18. Also, the end surface 114A of the waveguide 21 is processed to be a mirror surface, and is arranged to have a slope angle −θ6 (−8°) with respect to the Z-axis direction.

The end surface 112B is connected to the output-side optical fiber array 113. The end surface 112B includes an end surface 115B of the substrate 18 and an end surface 114B of the waveguide 21. A notch part 117B is formed on the end surface 115B of the substrate 18. Also, the end surface 114B of the waveguide 21 is processed to be a mirror surface, and is arranged to have a slope angle +θ7 (+8°) with respect to the Z-axis direction.

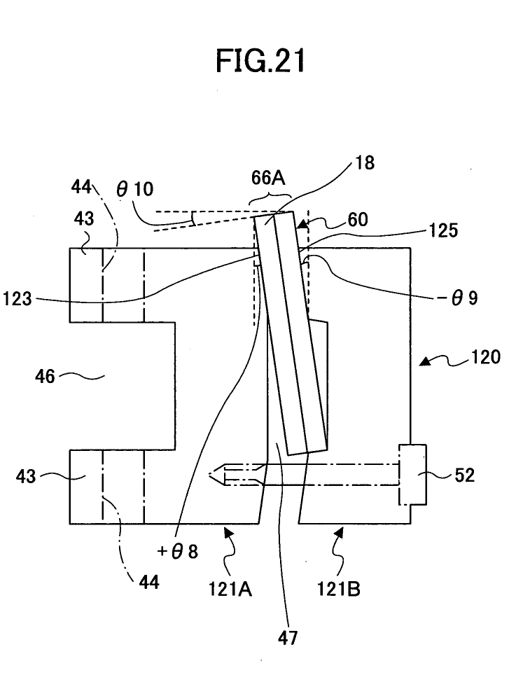

A holding unit 120 according to thee second embodiment is described with reference to FIG. 21. FIG. 21 roughly shows an exemplary structure of the holding unit 120. In FIG. 21, the same components as those of the holding unit 40 shown in FIG. 8 are designated by the same reference numerals.

The holding unit 120 keeps an optical waveguide device 60 to be processed. The holding unit 120 mainly includes a fixing-side member 121A, a holding-side member 121B and a screw 52. The fixing-side member 121A may be located at the side fixed to a mounted part 77 of a grinder 70 (see FIG. 10) or a mounted part 182 of a polisher 90 (see FIG. 13). The fixing-side member 121A is provided with two convex parts 43, a concave part 46, holes 44 and a slope surface 123. The slope surface 123 is formed to have a slope angle +θ8 (+8°) with respect to the Z-axis direction. When the optical waveguide device 60 is held, the slope surface 123 is in contact with the optical waveguide device 60. In this embodiment, the optical waveguide device 60 is retained in the holding unit 120 in such a way that the substrate 18 can remain in contact with the slope surface 123.

The holding-side member 121B is provided with a slope surface 125 in contact with the optical waveguide device 60. The slope surface 125 is formed to have a slope angle −θ9 (−8°) with respect to the Z-axis direction. The slope surface 125 is positioned to face the slope surface 123 in parallel.

An area 47 to insert a plurality of optical waveguide devices 60 is formed between the slope surfaces 123 and 125. The plurality of optical waveguide devices 60 inserted in the area 47 are held via the slope surface 125 of the holding-side member 121B. The holding unit 120 holds the optical waveguide devices 60 in such a way that end surfaces of the optical waveguide devices 60 can be oriented at a slope angle θ10 with respect to the X-axis direction. The three screws 52 are used to fix the holding-side member 121B toward the fixing-side member 121A.

After the holding unit 120 is used to form notch parts 117A and 117B on the substrate 18 by grinding, the end surfaces 64A and 64B of the waveguide 21 are polished. As a result, since end surfaces 114A and 114B of the waveguide 21 can be formed as sloped mirror surfaces in shorter processing time than that any of conventional methods, it is possible to improve productivity of the optical waveguide device 112. It is noted that also in the second embodiment, the grinder 70 and the polisher 90 can be used to manufacture the optical waveguide device 112 in the same way as the first embodiment.

Although the first and second embodiments have been described for the purpose of explaining the present invention, the present invention is not limited to these embodiments. For example, the present invention simply requires that a notch part be formed in an end surface of a substrate before polishing and then an end surface of a waveguide be polished, and the present invention is not limited to the slope angles and shape of end surfaces shown in the first and second embodiments. Also, although the case of processing an end surface of a waveguide provided in an optical waveguide device has been described in the first and second embodiments, an end surface of an optical fiber array or an optical fiber may be processed in accordance with the above-mentioned grinding and polishing method.

The present invention is not limited to the specifically disclosed embodiments, and variations and modifications may be made without departing from the scope of the present invention.

The present application is based on Japanese Patent Priority Application No. 2003-435196 filed Dec. 26, 2003, the entire contents of which are hereby incorporated by reference.

1. An optical waveguide device, comprising:
an end surface having a substrate, a clad layer on the substrate and a waveguide included in the clad layer,
wherein the end surface is connected to an optical fiber array having at least one optical fiber via adhesive, the waveguide has an end surface sloped by a slope angle θ with respect to a direction orthogonal to an optical axis thereof, and the substrate has a notch part on an end surface thereof.

2. A method of manufacturing an optical waveguide device comprising an end surface having a substrate, a clad layer being on the substrate and a waveguide included in the clad layer, wherein the end surface is connected to an optical fiber array having at least one optical fiber via adhesive, the waveguide has an end surface sloped by a slope angle θ with respect to a direction orthogonal to an optical axis thereof, and the substrate has a notch part on an end surface thereof, the method comprising steps of:
forming the notch part on the end surface of the substrate by grinding the end surface; and
polishing the end surface of the waveguide to have the slope angle θ.

3. The method as claimed in claim 2, wherein the notch part forming step uses a grinder to form the notch part, and the end surface polishing step uses a polisher to polish the end surface.

4. The method as claimed in claim 3, further comprising a step of:
providing a holding unit holding the optical waveguide device,
wherein the grinder has a mounted part to mount the holding unit, the polisher has a mounted part to mount the holding unit, and the holding unit is configured to be attachable to the mounted part of the grinder and the mounted part of the polisher.

5. The method as claimed in claim 3, wherein the grinder and the polisher have respective processing members processing the optical waveguide device, and the holding unit holds the optical waveguide device in such a way that the end surface of the waveguide is sloped by the slope angle θ with respect to the processing members.
